(19) United States
(12) Patent Application Publication
(10) Pub. No.: US 2026/0324073 A1
(43) Pub. Date: Oct. 15, 2026

(54) DISPLAY PANEL AND DISPLAY APPARATUS

(71) Applicant: WUHAN TIANMA MICRO-ELECTRONICS CO., LTD., Wuhan (CN)

(72) Inventor: Wenshuai ZHANG, Wuhan (CN)

(73) Assignee: WUHAN TIANMA MICRO-ELECTRONICS CO., LTD., Wuhan (CN)

(21) Appl. No.: 18/871,422

(22) PCT Filed: Feb. 7, 2024
(86) PCT No.: PCT/CN2024/076643

§ 371 Date: Dec. 3, 2024

(30) Foreign Application Priority Data
Nov. 28, 2023 (CN) 202311614126.3

(51) Int. Cl. H10D 86/40; H10D 86/60

(52) U.S. Cl. CPC H10D 86/441; H10D 86/60

(57) ABSTRACT

A display panel and a display apparatus. The display panel includes a substrate, first connection lines, data lines, bonding pads, and pixel circuits. The first connection lines and data lines are located in a display region, the bonding pads are located in a non-display region, and one end of each first connection lines is coupled to one data line and the other end of the each first connection line is coupled to one bonding pad. The first connection lines include first line segments extending in a first direction and second line segments extending in a second direction. The data lines extend in the second direction. At least one first connection lines includes at least two first line segments arranged at intervals. The pixel circuits are arranged in pixel circuit rows in the first direction. The first line segments of two adjacent first connection lines overlap different pixel circuit rows, respectively.

The present disclosure claims priority to Chinese Patent Application No. 202311614126.3 entitled “DISPLAY PANEL AND DISPLAY APPARATUS” filed on Nov. 28, 2023, the content of which is incorporated herein by reference in its entirety.

### TECHNICAL FIELD

The present disclosure relates to the field of display technology and, in particular, to a display panel and a display apparatus.

### BACKGROUND

In the prior art, data connection lines are disposed in a display region, and some data lines are connected to data terminals through the data connection lines. As such, the data connection lines that were originally disposed at a lower corner of a display panel can be removed, thereby achieving the purpose of compressing the lower bezel of the display panel. Currently, the scheme of disposing of the data connection lines in the display region has a problem of display twill, which affects the display effect.

### SUMMARY

Embodiments of the present disclosure provide a display panel and a display apparatus to solve the technical problem and improve the display effect.

In a first aspect, an embodiment of the present disclosure provides a display panel including: a substrate, and a plurality of first connection lines, a plurality of data lines, a plurality of bonding pads, and a plurality of pixel circuits located on a side of the substrate; and a display region and a non-display region. The first connection lines and the data lines are both located in the display region, the bonding pads are located in the non-display region, and one end of each of the first connection lines is coupled to one of the data lines and the other end of the each of the first connection lines is coupled to one of the bonding pads. The first connection lines include first line segments extending in a first direction and second line segments extending in a second direction, and the first direction intersects the second direction. The data lines extend in the second direction, and at least one of the first connection lines includes at least two first line segments arranged at intervals. The plurality of pixel circuits are arranged in pixel circuit rows in the first direction, and the first line segments of two adjacent first connection lines overlap different pixel circuit rows, respectively.

In a second aspect, based on the same inventive concept, an embodiment of the present disclosure further provides a display apparatus including the display panel provided by any embodiment of the present disclosure.

The display panel and the display apparatus provided by the embodiments of the present disclosure have the following beneficial effects: by providing in the display panel at least one of the first connection lines to include at least two first line segments arranged at intervals and the first line segments of two adjacent first connection lines to overlap different pixel circuit rows respectively, the first line segments of the two adjacent first connection lines form coupling capacitances with different scan lines respectively and the number of the first connection lines influenced by the same scan line can be reduced, thereby reducing the coupling effect between the scan line and the first connection lines and improving the display effect.

### BRIEF DESCRIPTION OF DRAWINGS

In order to illustrate the technical solutions in the embodiments of the present disclosure or the technical solutions in the prior art more clearly, the accompanying drawings required to be used in the description of the embodiments or the prior art will be briefly introduced below. Apparently, the accompanying drawings in the following description are merely some of the embodiments of the present disclosure. Those ordinarily skilled in the art may still derive other accompanying drawings from these accompanying drawings without creative efforts.

FIG. 1 is a partial schematic diagram of a display panel in the related art;

FIG. 2 is a schematic diagram of a display panel provided by an embodiment of the present disclosure;

FIG. 3 is another partial schematic diagram of a display panel provided by an embodiment of the present disclosure;

FIG. 4 is another schematic diagram of a display panel provided by an embodiment of the present disclosure;

FIG. 5 is another schematic diagram of a display panel provided by an embodiment of the present disclosure;

FIG. 6 is another schematic diagram of a display panel provided by an embodiment of the present disclosure;

FIG. 7 is another schematic diagram of a display panel provided by an embodiment of the present disclosure;

FIG. 8 is another schematic diagram of a display panel provided by an embodiment of the present disclosure;

FIG. 9 is a timing diagram of a display panel provided by an embodiment of the present disclosure;

FIG. 10 is another schematic diagram of a display panel provided by an embodiment of the present disclosure;

FIG. 11 is another schematic diagram of a display panel provided by an embodiment of the present disclosure;

FIG. 12 is a schematic cross-sectional diagram taken along a cutting line A-A′ in FIG. 11;

FIG. 13 is another schematic diagram of a display panel provided by an embodiment of the present disclosure; and

FIG. 14 is a schematic diagram of a display apparatus provided by an embodiment of the present disclosure.

### DESCRIPTION OF EMBODIMENTS

To make the objectives, technical solutions, and advantages of the embodiments of the present disclosure clearer, the technical solutions in the embodiments of the present disclosure will be clearly and completely described below with reference to the accompanying drawings in the embodiments of the present disclosure. Apparently, the described embodiments are some rather than all of the embodiments of the present disclosure. All other embodiments obtained by those ordinarily skilled in the art based on the embodiments of the present disclosure without creative efforts should fall within the protection scope of the present disclosure.

Various modifications and variations can be made in the present disclosure without departing from the spirit or scope of the present disclosure, which is apparent to those skilled in the art. Therefore, the present disclosure is intended to cover the modifications and variations of the present disclosure that fall within the scope of the corresponding claims (claimed technical solutions) and their equivalents. It should be noted that the implementations provided by the embodiments of the present disclosure can be combined with each other without contradiction.

Terms used in the embodiments of the present disclosure are only for the purpose of describing specific embodiments, and are not intended to limit the present disclosure. Unless otherwise indicated clearly in the context, words, such as “a”, “the”, and “this”, in a singular form in the embodiments and appended claims of the present disclosure are also intended to represent the plural form.

It should be understood that although the terms “first” and “second” may be used to describe XX in the embodiments of the present disclosure, these XXs should not be limited by these terms. These terms are merely used to distinguish the XXs from one other.

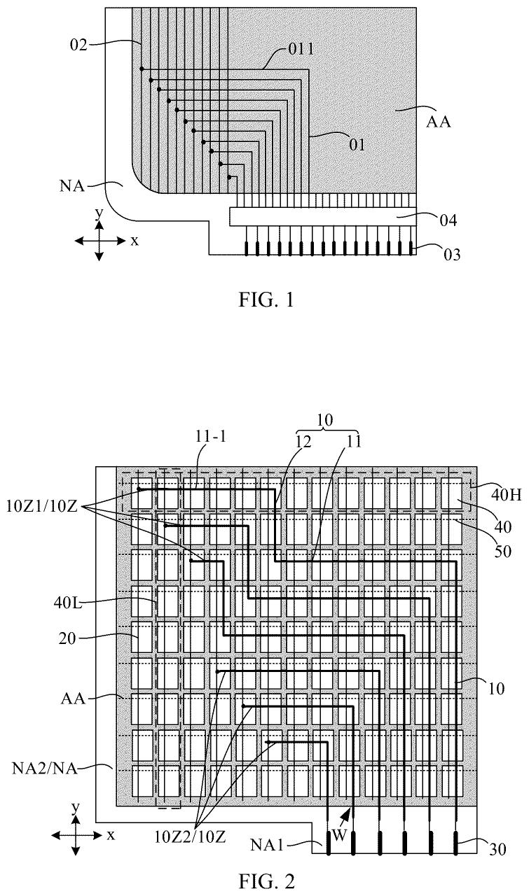

FIG. 1 is a partial schematic diagram of a display panel in the related art. As shown in FIG. 1, data connection lines 01 are disposed in a display region AA, one end of each of the data connection lines 01 is coupled to a data line 02, the other end of the each of the data connection lines 01 is coupled to a data terminal 03. A demultiplexer circuit 04 may be disposed in a non-display region NA. The data connection lines 01 may be coupled to the data terminals 03 through the demultiplexer circuit 04. The demultiplexer circuit 04 may include a plurality of demultiplexers. A demultiplexer may be coupled to at least two data lines 02. That is, there is a demultiplexer coupled to at least two data connection lines 01. The data connection lines 01 include first line segments 011 extending in a first direction x. The data lines 02 extend in a second direction y, and scan lines (not shown in FIG. 1) extending in the first direction x are further disposed in the display region AA. The first line segments 011 may extend in the same direction as the scan lines. The distance between a first line segment 011 and a scan line is relatively close during wiring, resulting in a large coupling capacitance therebetween. When a signal is provided on the scan line, the first line segment 011 adjacent to the scan line is coupled by the scan line, so that a data voltage transmitted on the first line segment 011 fluctuates, thereby causing display twill to appear. By disposing the demultiplexer circuit 04 in the non-display region NA, the number of the data terminals 03 provided can be reduced, but after a switch in the demultiplexer is turned off, the data connection line 01 connected to the switch is in a floating state. At this point, the data connection line 01 is more susceptible to being coupled by the scan line, such that the phenomenon of display twill is exacerbated and the display effect is seriously affected.

In order to solve the problem existing in the related art, the embodiment of the present disclosure provides a display panel, in which the first connection lines are disposed in the display region to realize electrical connection between a part of the data lines and the data terminals. At least a part of the first connection lines include at least two first line segments, and an extension direction of the first line segments intersects an extension direction of the data lines, thereby being capable of dispersing the coupling between a first connection line and a scan line to the couplings between the first line segments of the first connection line and different scan lines, which can alleviate the degree that the first connection line is coupled by the scan line each time, thereby weakening the influence of the coupling on a data signal and improving the display effect. In addition, it is further provided that the first line segments of two adjacent first connection lines overlap different pixel circuit rows respectively such that the first line segments of the two adjacent first connection lines are coupled by different scan lines respectively, thereby being able to reduce the number of the first connection lines affected by the same scan line.

FIG. 2 is a schematic diagram of a display panel provided by an embodiment of the present disclosure. As shown in FIG. 2, the display panel includes a plurality of first connection lines 10, a plurality of data lines 20, a plurality of bonding pads 30, and a plurality of pixel circuits 40. The first connection lines 10 and the data lines 20 are both located in a display region AA. The bonding pads 30 are located in a non-display region NA. One end of each of the first connection lines 10 is coupled to one of the data lines 20, and the other end of the each of the first connection lines 10 is coupled to one of the bonding pads 30. The display panel further includes a substrate (not shown in FIG. 2), and the pixel circuits 40, the bonding pads 30, the data lines 20, and the first connection lines 10 are all located on a same side of the substrate.

The first connection lines 10 include first line segments 11 extending in a first direction x and second line segments 12 extending in a second direction y. The first direction x intersects the second direction y. The data lines 20 extend in the second direction y, and at least one of the first connection lines 10 include at least two first line segments 11 arranged at intervals.

The plurality of pixel circuits 40 are arranged in pixel circuit rows 40H in the first direction x; and the first line segments 11 of two adjacent first connection lines 10 overlap different pixel circuit rows 40H, respectively. It can be understood that a transistor and a signal line are arranged in each of the pixel circuits 40, and each of the pixel circuits 40 occupies a certain area in both the first direction x and the second direction y. A first connection line 10 overlapping the transistor or the signal line in a pixel circuit 40 is considered as the first connection line 10 overlapping a pixel circuit row 40H.

The display panel further includes scan lines 50 extending in the first direction x. The scan lines 50 are illustrated by dotted lines in FIG. 2. The pixel circuits 40 are coupled to the scan lines 50, and the scan lines 50 are configured to drive the pixel circuit rows 40H. The first line segments 11 of the first connection lines 10 are closer to the scan lines 50, and coupling capacitances are formed between the first line segments 11 and the scan lines 50.

By providing in the display panel provided by the embodiment of the present disclosure at least one of the first connection lines 10 including at least two first line segments 11 arranged at intervals (for example, two first line segments of the same first connection line are electrically connected through at least one second line segment) and the first line segments 11 of two adjacent first connection lines 10 overlapping different pixel circuit rows 40H respectively such that the first line segments 11 of the two adjacent first connection lines 10 form coupling capacitances with different scan lines 50 respectively, the number of the first connection lines 10 influenced by the same scan line 50 can be reduced, thereby reducing the coupling effect between the scan line 50 and the first connection lines 10 and improving the display effect.

In addition, in the first connection lines 10 including at least two first line segments 11, each of the first line segments 11 may be provided to overlap a different pixel circuit row 40H. Therefore, a relatively small capacitance is formed between the each of the first line segments 11 and the scan line 50 driving the pixel circuit row 40H, and by providing the scan lines 50 overlapping the individual first line segments 11 of the same first connection line 10 to be not provided with signals at the same time, the degree that the first connection line 10 is coupled by the scan line each time can be alleviated. In the process of displaying a frame of picture, the number of times the first connection line 10 is coupled is equal to the number of the first line segments 11 included in the first connection line 10. The degree that the first connection line 10 is coupled each time is smaller and can be ignored, and the coupling on the individual first line segments 11 does not accumulate, thereby weakening the influence of the coupling on the data signal on the first connection line 10 and improving the display effect.

In some implementations, as shown in FIG. 2, the display panel includes at least one connection line group 10Z, each of the at least one connection line group 10Z includes at least two first connection lines 10 arranged in sequence, and the first connection lines 10 in each of the connection line groups 10Z include a same number of the first line segments 11. A coupling capacitance is formed between the first line segment 11 and the scan line 50, and when the scan line 50 is provided a scan signal, the coupling effect between the first line segment 11 and the scan line 50 affects a data signal on the first connection line 10. By providing the first connection lines 10 in each of the connection line groups 10Z to include a same number of the first line segments 11, the number of times the individual first connection lines 10 in the same connection line group 10Z are coupled by the scan lines 50 is equal and the difference in the degree that the individual first connection lines 10 are coupled by the scan lines 50 each time is small, thereby being capable to cause the difference in the influence of the data signals transmitted by the individual first connection lines 10 in each of the connection line groups 10Z due to the coupling to be small, whereby the display uniformity can be further improved.

Two connection line groups 10Z are illustrated in FIG. 2, in which each of the first connection lines 10 in one connection line group 10Z includes two first line segments 11, and each of the first connection lines 10 in the other connection line group 10Z includes one first line segment 11. For one first connection line 10, the first line segment 11 and the second line segment 12 connected thereto may form a step shape.

In some implementations, as shown in FIG. 2, the connection line groups 10Z include a first connection line group 10Z1 and a second connection line group 10Z 2. The first connection lines 10 in the first connection line group 10Z1 each include n₁ first line segments 11, the first connection lines 10 in the second connection line group 10Z2 each includes n₂ first line segments 11, both n₁ and n₂ are positive integers, where n₁>n₂. The number of the first connection lines 10 included in different connection line groups 10Z may be the same or different. The number of the first line segments 11 included in a single first connection line 10 is set to be different in different connection line groups 10Z, the number of the first line segments 11 of the first connection lines 10 can be reasonably set to meet the wiring requirement for connecting the first connection lines 10 and the data lines 20. Meanwhile, it can also be ensured that the length of each of the first line segments 11 is not too long, thereby being capable of ensuring that the coupling capacitance between each of the first line segments 11 and the scan line 50 is smaller.

As shown in FIG. 2, the non-display region NA includes a first non-display region NA1 located on a side of the display region AA in the second direction y. The bonding pads 30 are located in the first non-display region NA1. The plurality of the first line segments 11 in the first connection line group 10Z1 are located on a side of the second connection line group 10Z2 away from the first non-display region NA1. It can be seen from FIG. 2 that the intersection of each of the first connection lines 10 with the boundary between the display region AA and the first non-display region NA1 is W. In the first direction x, the distance between the intersection W of each of the first connection lines 10 in the first connection line group 1 0Z1 and the data line 20 connected thereto is greater than the distance between the intersection W of each of the first connection lines 10 in the second connection line group 10Z2 and the data line 20 connected thereto. The total length of the first line segments 11 of a single first connection line 10 in the first connection line group 1 0Z1 is greater than the total length of the first line segments 11 of a single first connection line 10 in the second connection line group 10Z2. By setting the number of the first line segments 11 included in a single first connection line 10 in the first connection line group 10Z1 to be relatively larger, it can be ensured that the length of each of the first line segments 11 is not too long, whereby it can be ensured that the coupling capacitance between each of the first line segments 11 and the scan line 50 is smaller. Moreover, the difference between the length of a single first line segment 11 in the first connection line group 10Z1 and the length of a single first line segment 11 in the second connection line group 10Z2 can also be reduced, thereby reducing the difference in the influence of the different first connection lines 10 being coupled by the scan lines 50, which is conducive to improving the display uniformity.

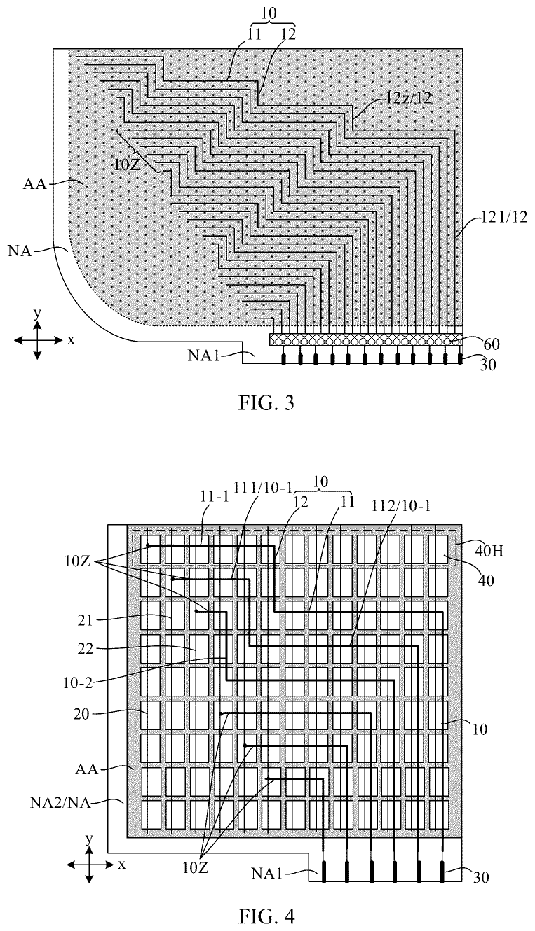

FIG. 2 illustrates only two connection line groups 10Z, and the embodiments of the present disclosure do not limit the number of the connection line groups 10Z including a plurality of the first connection lines 10 arranged in rows. FIG. 3 is another partial schematic diagram of a display panel provided by an embodiment of the present disclosure. In order to clearly illustrate the wiring condition of the first connection lines 10, the structures, such as pixel circuits, data lines, scan lines, or the like, are not shown in FIG. 3. FIG. 3 shows four connection line groups 10Z, and in a direction away from the first non-display region NA1, the number of the first line segments 11 included in a single first connection line 10 in the connection line group 10Z gradually increases.

As shown in FIG. 3, the first non-display region NA1 may further be provided with a demultiplexer circuit 60, and the first connection lines 10 are coupled to the bonding pads 30 through the demultiplexer circuit 60. The demultiplexer circuit 60 includes a first demultiplexer (not shown in FIG. 3), and an input end of the first demultiplexer is connected to one data terminal 30, and an output end of the first demultiplexer is connected to at least two first connection lines 10. By providing the demultiplexer circuit 60, the number of the data terminals 30 can be reduced, thereby reducing the number of the pins of a display driving chip and being conducive to reducing the manufacturing cost.

As shown in FIG. 2, the first connection line group 10Z1 and the second connection line group 10Z2 are adjacent to each other, where n₁−n₂=1. That is, the difference in the number of the first line segments 11 included in a single first connection line 10 in the two adjacent connection line groups 10Z is 1. Such an arrangement can make the difference in the length of the first connection line 10 in the adjacent connection line groups 10Z small, and the difference in the length of each of the first line segments 11 is also small, so that there is no sudden change in the load on each of the data lines 20 coupled to the first connection lines 10, and the difference in the influence of the coupling of the data line 50 on each of the first connection lines 10 is small, which is conducive to improving the display uniformity.

As shown in FIG. 2, at least one of the first connection lines 10 includes a first one first line segment 11-1, and the first one first line segment 11-1 is the first line segment of the each of the first connection lines 10 which is furthest away from the first non-display region NA1. Optionally, the first one first line segment 11-1 is electrically connected to the data line 20 through a via (such as a black dot shown in FIG. 2). In a direction away from the first non-display region NA1, lengths of a plurality of the first one first line segments 11-1 in one of the connection line groups 10Z gradually increase. Such an arrangement can meet the wiring requirement for the connection between the first connection lines 11 in the connection line groups 10Z and the corresponding data lines 20. Meanwhile, the lengths of the first connection lines 11 in each of the connection line groups 10Z can gradually vary to prevent a sudden change in length, thereby reducing the load difference among the data lines 20 correspondingly connected to the connection line group 10Z and improving the display uniformity.

In some implementations, FIG. 4 is another schematic diagram of a display panel provided by an embodiment of the present disclosure. As shown in FIG. 4, the non-display region NA includes a first non-display region NA1 and a second non-display region NA2, and the second non-display region NA2 is located on a side of the display region AA in the first direction x. The bonding pads 30 are located in the first non-display region NA1. The data lines 20 include a first data line 21 and a second data line 22, and a distance between the first data line 21 and the second non-display region NA2 is less than a distance between the second data line 22 and the second non-display region NA2. A first line segment of each of the first connection lines 10 which is furthest away from the first non-display region NA1 is the first one first line segment 11-1. The first connection lines 10 in one connection line group 10Z include a first-type first connection line 10-1 and a second-type first connection line 10-2, a length of the first one first line segment 11 of the first-type first connection line 10-1 is greater than a length of the first one first line segment 11 of the second-type first connection line 10-2, the first-type first connection line 10-1 is coupled to the first data line 21, and the second-type first connection line 10-2 is coupled to the second data line 22. Such an arrangement not only enables the lengths of the first connection lines 10 in one connection line group 20Z to gradually vary, but also enables the lengths of the plurality of first connection lines 10 arranged in sequence to gradually vary, thereby preventing the sudden changes in the lengths of the two first connection lines 10 which are adjacent to each other and belong to two connection line groups 20Z, which can reduce the load difference between the data lines 20 and be conducive to improving the display uniformity.

In embodiments of FIG. 4, the farther the first one first line segment 11 of the first connection line 10 is from the first non-display region NA1, the closer the data line 20 connected to the first connection line 10 is from the second non-display region NA2.

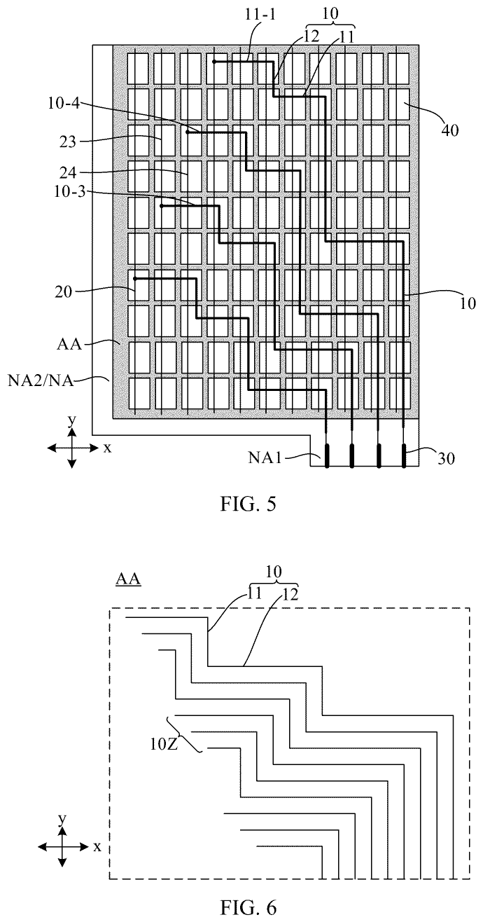

In some other implementations, FIG. 5 is another schematic diagram of a display panel provided by an embodiment of the present disclosure. As shown in FIG. 5, the non-display region NA includes a first non-display region NA1 and a second non-display region NA2. The first non-display region NA1 is located on a side of the display region AA in the second direction y, and the second non-display region NA2 is located on a side of the display region AA in the first direction x. The first line segment 11 of the each of the first connection lines 10 which is furthest away from the first non-display region NA1 is the first one first line segment 11-1. The first connection lines 10 include a third-type first connection line 10-3 and a fourth-type first connection line 10-4, and a first one first line segment 11-1 of the fourth-type first connection line 10-4 is located on a side of the third-type first connection line 10-3 away from the first non-display region NA1. The data lines 20 include a third data line 23 and a fourth data line 24. A distance between the third data line 23 and the second non-display region NA2 is less than a distance between the fourth data line 24 and the second non-display region NA2. The third-type first connection line 10-3 is coupled to the third data line 23, and the fourth-type first connection line 10-4 is coupled to the fourth data line 24. In this embodiment, the farther the first one first line segment 11 of the first connection line 10 is from the first non-display region NA1, the farther the data line 20 connected to the first connection line 10 is from the second non-display region NA2. Such an arrangement can make the total length difference of the first connection lines 10 small, which can reduce the load difference between the data lines 20 and be conducive to improving the display uniformity.

In some implementations, in a direction perpendicular to a plane where the substrate is located, each of the first line segments 11 overlaps k pixel circuits in one of the pixel circuit rows 40H, where 5%K≤k≤25%K, both k and K are positive integers, and K is a total number of the pixel circuits included in the one of the pixel circuit rows 40H. In the embodiment of the present disclosure, each of the first line segments 11 overlaps dozens or even hundreds of pixel circuits. Each of the first line segments 11 overlaps a relatively large number of pixel circuits, and correspondingly, the total length of the second line segments 12 in one first connection line 10 will be relatively smaller, thereby causing the length occupied by the one first connection line 10 in the second direction y to be smaller. Therefore, the total area occupied by the plurality of the first connection lines 10 in the display region is also relatively smaller, whereby more wiring space can be reserved in the display region for other wiring designs.

In some implementations, at least two of the first line segments which have an equal length are provided in at least one of the first connection lines 10. It should be noted that there may be a process error in the production of the display panel, and there may also be a measurement error when measuring the length. Here, the term “equal length” as used in the present disclosure means lengths that are substantially equal taking into account both process error and measurement error. The longer the length of the first line segment 11 is, the greater the coupling capacitance between the first line segment 11 and the adjacent scan line will be. For the first line segments 11s with the same length, the coupling capacitances formed by the first line segments 11 and the scan lines are also equal. The same first connection line 10 including the first line segments 11 of equal length is conducive to relatively uniformly dispersing the coupling between the first connection line 10 and the scan line to different first line segments 11.

In some implementations, in at least one of the first connection lines 10, lengths of the first line segments 11 sequentially arranged in a wiring direction of the at least one of the first connection lines gradually vary. Each of the first line segments 11 of each of the first connection lines 10 overlaps a different pixel circuit row to form a coupling capacitance, and the lengths of the first line segments 11 gradually vary in the wiring direction, and thus the coupling capacitances formed between the first line segments 11 and the scan lines gradually vary. Therefore, in displaying a frame of picture, the degree that the first connection lines 10 are coupled multiple times, reducing the difference between the coupling degrees before and after, thereby being capable of reducing the amplitude of the fluctuations of the data signals on the first connection lines 10.

FIG. 6 is another schematic diagram of a display panel provided by an embodiment of the present disclosure. FIG. 6 illustrates only a partial region of the display region AA. It can be seen from FIG. 6 that, for one first connection line 10, lengths of the first line segments 11 sequentially arranged in a wiring direction from left to right gradually increase.

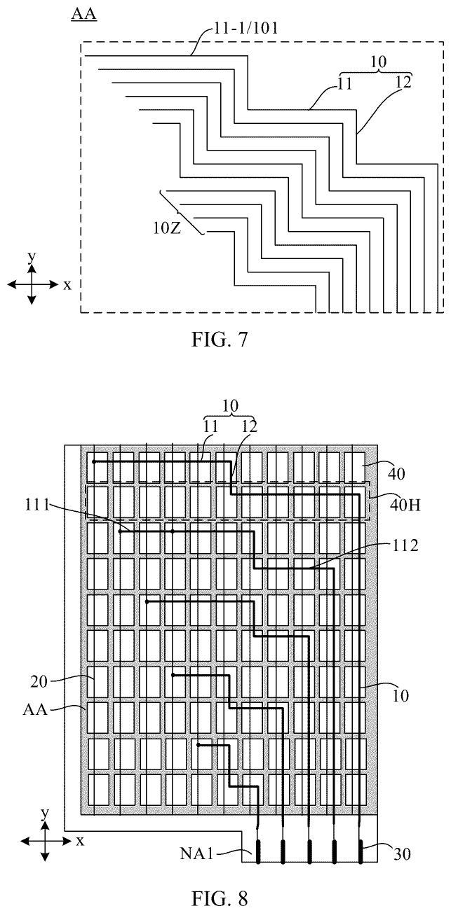

FIG. 7 is another schematic diagram of a display panel provided by an embodiment of the present disclosure. As shown in FIG. 7, each of the connection line groups 10Z includes a first one first connection line 101. The length of the first one first line segment 11-1 of the first one first connection line 101 is the longest, and the lengths of the first line segments 11 of the first one first connection line 101 which are sequentially arranged in a wiring direction from left to right gradually decrease. It can be seen from FIG. 7 that from top to bottom, the lengths of the first one first line segments 11-1 in one connection line group 10Z gradually decrease. Some of the first connection lines 10 in the connection line group 10Z satisfy that the lengths of the first line segments 11 sequentially arranged in the wiring direction from left to right gradually decrease, while the remaining first connection lines 10 satisfy that the lengths of the first line segments 11 sequentially arranged in the wiring direction from left to right gradually decrease, except for the first one first line segment 11-1.

As shown in FIG. 3, the second line segments 12 include middle line segment(s) 12z. Two ends of each of the middle line segments 12z are respectively connected to one of the first line segments 11, and a length of each of the middle line segments 12z is less than a length of the first line segment 11 connected thereto. Such an arrangement can reduce the span of a single first connection line 10 in the second direction y, which is conducive to reducing the total length occupied by a plurality of the first connection lines 10 in the second direction y and saving the wiring space in the display region. Therefore, more space can be reserved in the display region to provide the dummy lines, which can be used to transmit constant voltage signals (such as a power signal or a reset signal required by the pixel circuits) to reduce the signal voltage drop and improve the signal uniformity within the display panel.

As shown in FIG. 3, each of the second line segments 12 further includes a first one second line segment 121, and the first one second line segment 121 is a second line segment 12 of the first connection line 10 which extends to a boundary position between the display region AA and the first non-display region NA1. It can be seen from FIG. 3 that the first one second line segments 121 of the plurality of first connection lines 10 gradually become longer from left to right.

In some implementations, the first line segments 11 includes a first sub-line segment and a second sub-line segment, and one second line segment 12 is connected between the first sub-line segment and the second sub-line segment. That is, the first sub-line segment and the second sub-line segment belong to the same first connection line 10. The pixel circuit row 40H overlapping the first sub-line segment and the pixel circuit row 40H overlapping the second sub-line segment are spaced by m pixel circuit rows 40H, where m is an integer, and m≥0.

As shown in FIG. 2, in each of the first connection lines 10, m=1, that is, the first sub-line segment 111 and the second sub-line segment 112 is separated by one pixel circuit row 40H. That is, in addition to the pixel circuit row 40H overlapping the first sub-line segment 111 and the pixel circuit row 40H overlapping the second sub-line segment 112, there is a complete pixel circuit row 40H between the first sub-line segment 111 and the second sub-line segment 112.

FIG. 8 is another schematic diagram of a display panel provided by an embodiment of the present disclosure. As shown in FIG. 8, in each of the first connection lines 10, the first sub-line segment 111 and the second sub-line segment 112 are separated by 0 pixel circuit row 40H. That is, the pixel circuit rows 40H respectively overlapping the first sub-line segment 111 and the second sub-line segment 112 are two adjacent pixel circuit rows 40H. Such an arrangement can make the length of the second line segment 12 between the first sub-line segment 111 and the second sub-line segment 112 shorter, which is conducive to reducing the total length occupied by each of the plurality of first connection lines 10 in the second direction y and saving the wiring space in the display region.

Where m≥1, there is a certain distance between the first sub-line segment 111 and the second sub-line segment 112, and thus wiring may be performed between the first sub-line segment 111 and the second sub-line segment 112. For example, a dummy line is arranged between the row where the first sub-line segment 111 is located and the row where the second sub-line segment 112 is located. By transmitting a constant voltage signal through the dummy line, the signal voltage drop can be reduced and the signal uniformity within the display panel can be improved.

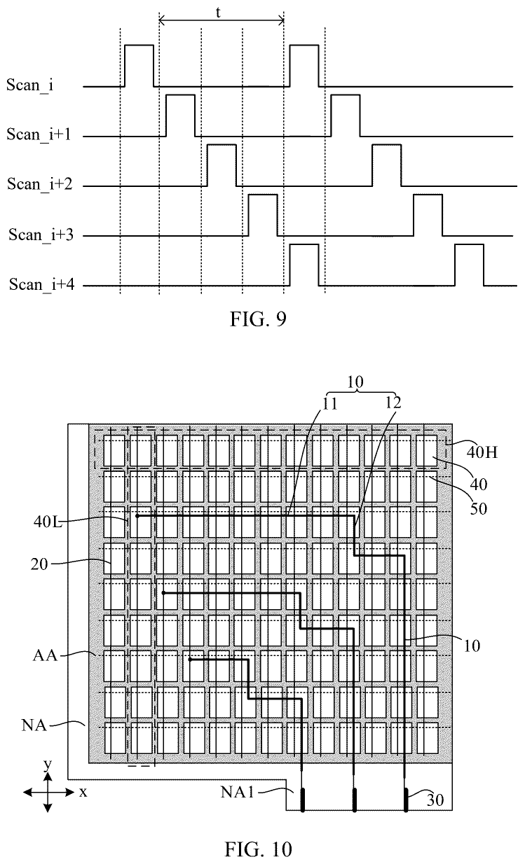

In some implementations, in displaying a frame of picture, signals provided on the scan lines each include q valid level periods, where q is an integer and q≥2; interval time between two adjacent valid level periods of a same scan line is t, a total time for n scan lines to output sequentially one valid level is t, where n is an integer and n≥1; and wherein m≠n. Taking q=2 and n=3 as an example, FIG. 9 is a timing diagram of a display panel provided by an embodiment of the present disclosure, and illustrates the timing the signals of 5 scan lines arranged in sequence. The 5 scan lines are Scan_i, Scan_i+1, Scan_i+2, Scan_i+3, and Scan_i+4, and i is a positive integer. The signal provided on each of the scan lines includes 2 valid level periods (as indicated by high levels), a time interval between two adjacent valid level periods on the same scan lines is t, and three scan lines sequentially output a valid level once in time t. That is, one scan line and another scan line which is spaced apart from it by three pixel circuit rows 40H may simultaneously provide valid level signals. In the embodiment of the present disclosure, by setting m/n, that is, m<n or m>n, it can be ensured that the two pixel circuit rows respectively overlapping the first sub-line segment 111 and the second sub-line segment 112 are not driven at the same time, and the first sub-line segment 111 and the second sub-line segment 112 are not coupled with the corresponding scan lines at the same time, which can alleviate the degree that the first connection line 10 is coupled by the scan lines each time.

As shown in FIG. 2, a plurality of the pixel circuits 40 are arranged in a pixel circuit column 40L in the second direction y. In a direction perpendicular to a plane where the substrate is located, each of the second line segments 12 at least partially overlaps the pixel circuit column 40L, and two adjacent second line segments 12 in different first connection lines 10 respectively overlap two adjacent pixel circuit columns 40L. Such an arrangement can make the adjacent second line segments 12 belonging to different first connection lines 10 to be closely arranged, which is conducive to reducing the area occupied by the plurality of first connection lines 10 in the display region, thereby saving the wiring space in the display region. In some implementations, more space can be reserved in the display region to provide the dummy lines. Transmitting the constant voltage signals through the dummy lines can reduce the signal voltage drop and improve the signal uniformity within the display panel.

In some other implementations, FIG. 10 is another schematic diagram of a display panel provided by an embodiment of the present disclosure. As shown in FIG. 10, a plurality of the pixel circuits 40 are arranged in a pixel circuit column 40L in the second direction y, and at least partially adjacent two second line segments 12 of different first connection lines 10 are separated by p pixel circuit columns, where p is an integer, and p≥1. As shown in FIG. 10, in addition to the two pixel circuit columns 40L overlapping two adjacent second line segments 12, there is a complete pixel circuit column 40L between the two adjacent second line segments 12, that is, p=1. In this implementation, the arrangement of two adjacent second line segments 12 belonging to different first connection lines 10 is relatively sparse, so that there is a space between the two adjacent second line segments 12 to arrange a dummy line. After a constant voltage signal is applied to the dummy line, the dummy line act as a shield to prevent signal interference between the adjacent second line segments 12.

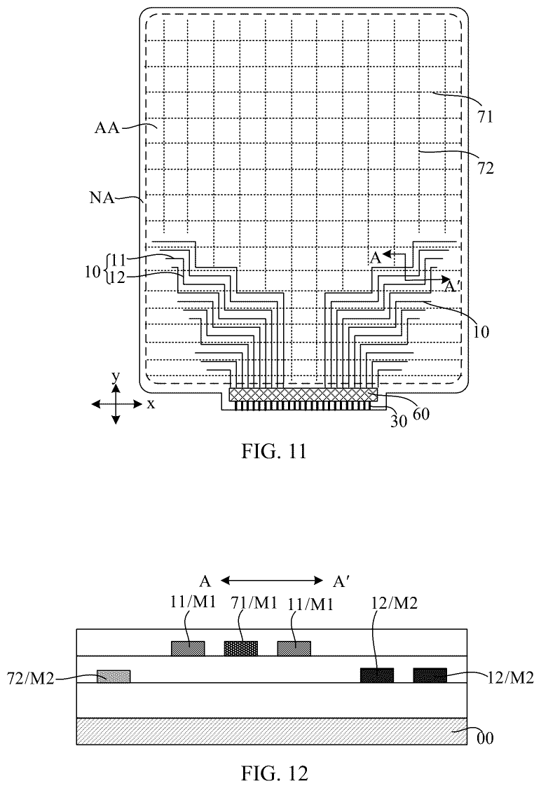

In some implementations, FIG. 11 is another schematic diagram of a display panel provided by an embodiment of the present disclosure, and FIG. 12 is a schematic cross-sectional diagram taken along a cutting line A-A′ in FIG. 11. As shown in FIG. 11, the display region AA includes first dummy lines 71 extending in the first direction x and second dummy lines 72 extending in the second direction y. The first dummy lines 71 are configured to transmit constant voltage signals, and the second dummy lines 71 are also configured to transmit constant voltage signals. In some implementations, the first dummy lines 71 and the second dummy lines 72 intersect and are electrically connected to each other, and thus they transmit the same signal. In some other implementations, the first dummy lines 71 and the second dummy lines 72 are insulated from each other and transmit different signals.

As shown in FIG. 12, the display panel includes a first metal layer M1 and a second metal layer M2 located on a side of the substrate 00. The first line segments 11 are located in the first metal layer M1, and the second line segments 12 are located in the second metal layer M2. The first dummy lines 71 are located in the first metal layer M1, and the second dummy lines 72 are located in the second metal layer M2. It is illustrated in FIG. 12 that the second metal layer M2 is located on a side of the first metal layer M1 close to the substrate 00. Therefore, other metal layers and semiconductor layers may also be provided between the second metal layer M2 and the substrate 00, for example, for manufacturing transistors and various signal lines. That is, the pixel circuits 40 may be located between the second metal layer M2 and the substrate 00.

In embodiments of FIG. 11, the first dummy lines 71 and the first line segments 11 which both have the same extension direction may be located in the same layer, and the second dummy lines 72 and the second line segments 12 which both have the same extension direction may be located in the same layer. After the plurality of the first connection lines 10 are arranged in the display region AA, the dummy lines may be arranged by using the remaining space, and the dummy lines are further used to transmit a constant voltage signal, which can reduce the signal voltage drop and improve the signal uniformity within the display panel.

It is illustrated in FIG. 11 that the first dummy lines 71 and the second dummy lines 72 are simultaneously arranged in the display region AA. In some other implementations, only the first dummy lines 71 or only the second dummy lines 72 may be arranged in the display region AA, which is illustrated in the drawings.

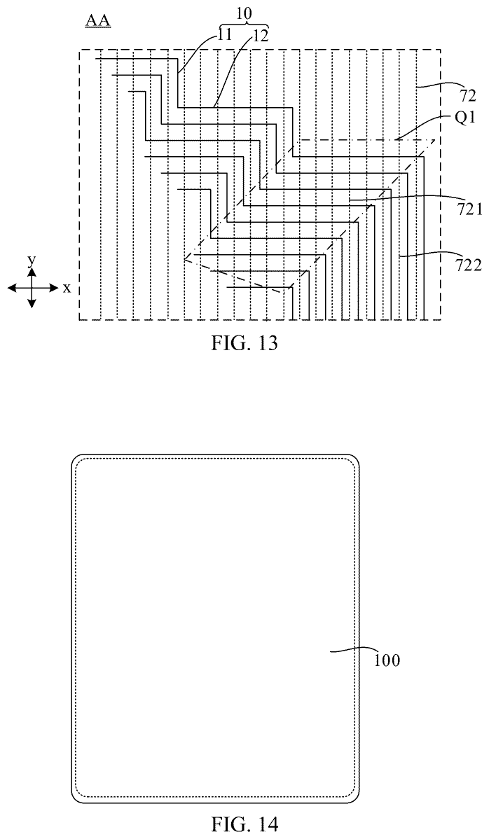

In some implementations, FIG. 13 is another schematic diagram of a display panel provided by an embodiment of the present disclosure. As shown in FIG. 13, second dummy lines 72 extending in the second direction y are disposed in the display region AA, and the second dummy lines 72 include first dummy line segments 721. In a direction perpendicular to a plane where the substrate 00 is located, at least one of the first dummy line segments 721 overlaps at least two first line segments 11. FIG. 13 illustrates that at least one of the first dummy line segments 721 overlaps a plurality of the first line segments 11 arranged in the second direction y. In the embodiment of the present disclosure, each of the first connection lines 10 includes at least one step (the first line segment 11 and the second line segment 12 which are connected to each other form a wiring like a step), and a part of the first connection lines 10 include at least two steps. Since each of the first line segments 11 overlaps dozens or even hundreds of pixel circuits, there is an arrangement region Q1 of the first line segments 11 as shown in FIG. 13, and the line segments of the second dummy lines 72 extending into the arrangement region Q1 are the first dummy line segments 721. By using the design in the embodiment of the present disclosure, the second dummy lines 72 can substantially run through the display region in the second direction y.

As shown in FIG. 13, the second dummy lines 72 include second dummy line segments 722, each of which is located between adjacent second line segments 12. When two adjacent second line segments 12 in different first connection lines 10 are separated by at least one pixel circuit column, a second dummy line segment 722 can be provided between the adjacent second line segments 12. The second dummy line segment 722 transmits a constant voltage signal, which can act as a shield to prevent signal interference between the adjacent second line segments 12.

In some implementations, the first dummy lines 71 include third dummy line segments overlapping at least two adjacent second line segments 12. Such an arrangement achieves that the dummy lines are provided in the arrangement region of the first connection lines 10. Optionally, the first dummy lines 72 include fourth dummy line segments located between two adjacent first line segments 11.

Based on the same inventive concept, an embodiment of the present disclosure further provides a display apparatus. FIG. 14 is a schematic diagram of the display apparatus provided by the embodiment of the present disclosure. As shown in FIG. 14, the display apparatus includes the display panel 100 provided by any of the embodiments of the present disclosure. The structure of the display panel 100 has been described in the above embodiments, and will not be repeated here. The display apparatus provided by the embodiment of the present disclosure may be, for example, an electronic product such as a mobile phone, a computer, a television, a smart watch, or the like.

The above description is merely for the preferred embodiments of the present disclosure, and is not intended to limit the present disclosure. Any modifications, equivalent replacements, improvements, and the like made within the spirit and principle of the present disclosure shall fall within the protection scope of the present disclosure.

Finally, it should be noted that the foregoing embodiments are merely intended to illustrate and not to limit the technical solutions of the present disclosure. Although the present disclosure has been described in detail with reference to the foregoing embodiments, those skilled in the art should understand that they can still make modifications to the technical solutions described in the foregoing embodiments or make equivalent replacements to some or all of the technical features thereof. These modifications or replacements do not make the essence of the corresponding technical solutions deviate from the scope of the technical solutions in the embodiments of the present disclosure.

1. A display panel, comprising:
a substrate;
a plurality of first connection lines comprising first line segments extending in a first direction and second line segments extending in a second direction, wherein the first direction intersects the second direction; and wherein at least one of the first connection lines comprises at least two first line segments arranged at intervals;
the plurality of pixel circuits are arranged in pixel circuit rows in the first direction, and wherein the first line segments of two adjacent first connection lines overlap different pixel circuit rows, respectively;
a display region, wherein the first connection lines and the data lines are both located in the display region; and
a non-display region, wherein the bonding pads are located in the non-display region, and one end of each of the first connection lines is coupled to one of the data lines and the other end of the each of the first connection lines is coupled to one of the bonding pads.

2. The display panel according to claim 1, wherein,
the display panel comprises at least one connection line group, each of the at least one connection line group comprising at least two first connection lines arranged in sequence, and the first connection lines in each of the at least one connection line group comprise a same number of the first line segments.

3. The display panel according to claim 2, wherein,
the at least one connection line group comprises a first connection line group and a second connection line group, the first connection lines in the first connection line group each comprise n₁ first line segments, the first connection lines in the second connection line group each comprise n₂ first line segments, and both n₁ and n₂ are positive integers, where n₁>n₂.

4. The display panel according to claim 3, wherein,
the non-display region comprises a first non-display region located on a side of the display region in the second direction, and the bonding pads are located in the first non-display region; and
the first line segments in the first connection line group are located on a side of the second connection line group away from the first non-display region.

5. The display panel according to claim 3, wherein,
the first connection line group is adjacent to the second connection line group, and n₁−n₂=1.

6. The display panel according to claim 2, wherein,
the non-display region comprises a first non-display region located on a side of the display region in the second direction, and the bonding pads are located in the first non-display region;
the first line segment(s) of each of the first connection lines comprises a first one first line segment, and the first one first line segment is the first line segment of the each of the first connection lines which is furthest away from the first non-display region; and
in a direction away from the first non-display region, lengths of a plurality of the first one first line segments in one of the at least one connection line group gradually increase.

7. The display panel according to claim 6, wherein,
the non-display region further comprises a second non-display region located on a side of the display region in the first direction, the data lines comprise a first data line and a second data line, and a distance between the first data line and the second non-display region is less than a distance between the second data line and the second non-display region; and
the first connection lines in each of the at least one connection line group comprise a first-type first connection line and a second-type first connection line, a length of the first one first line segment of the first-type first connection line is greater than a length of the first one first line segment of the second-type first connection line, the first-type first connection line is coupled to the first data line, and the second-type first connection line is coupled to the second data line.

8. The display panel according to claim 2, wherein,
the non-display region comprises a first non-display region and a second non-display region, the first non-display region is located on a side of the display region in the second direction, and the second non-display region is located on a side of the display region in the first direction;
the first line segment(s) of each of the first connection lines comprises a first one first line segment, and the first one first line segment is the first line segment of the each of the first connection lines which is furthest away from the first non-display region;
the first connection lines comprise a third-type first connection line and a fourth-type first connection line, and the first one first line segment of the fourth-type first connection line is located on a side of the third-type first connection line away from the first non-display region;
the data lines comprise a third data line and a fourth data line, and a distance between the third data line and the second non-display region is less than a distance between the fourth data line and the second non-display region; and
the third-type first connection line is coupled to the third data line, and the fourth-type first connection line is coupled to the fourth data line.

9. The display panel according to claim 1, wherein, in a direction perpendicular to a plane where the substrate is located, each of the first line segments overlaps k pixel circuits in one of the pixel circuit rows, where 5%K≤k≤25%K, both k and K are positive integers, and K is a total number of the pixel circuits comprised in the one of the pixel circuit rows.

10. The display panel according to claim 1, wherein,
at least two of the first line segments which have an equal length are provided in at least one of the first connection lines.

11. The display panel according to claim 1, wherein,
in at least one of the first connection lines, lengths of the first line segments sequentially arranged in a wiring direction of the at least one of the first connection lines gradually vary.

12. The display panel according to claim 1, wherein,
the second line segments comprise middle line segment(s), and two ends of each of the middle line segments are respectively connected to one of the first line segments; and
a length of each of the middle line segments is less than a length of the first line segment connected thereto.

13. The display panel according to claim 1, wherein,
the first line segments comprise a first sub-line segment and a second sub-line segment, and one second line segment is connected between the first sub-line segment and the second sub-line segment; and
the pixel circuit row overlapping the first sub-line segment and the pixel circuit row overlapping the second sub-line segment are separated by m pixel circuit row(s), where m is an integer and m≥0.

14. The display panel according to claim 13, wherein,
the display panel comprises a plurality of scan lines coupled to the pixel circuit rows; and
in displaying a frame of picture, signals provided on the scan lines each comprise q valid level periods, where q is an integer and q≥2; interval time between two adjacent valid level periods of a same scan line is t, a total time for n scan lines to output sequentially one valid level is t, where n is an integer and n≥1; and wherein m≠n.

15. The display panel according to claim 1, wherein,
a plurality of the pixel circuits are arranged in a pixel circuit column in the second direction; and
in a direction perpendicular to a plane where the substrate is located, each of the second line segments at least partially overlaps the pixel circuit column, and two adjacent second line segments in different first connection lines respectively overlap two adjacent pixel circuit columns.

16. The display panel according to claim 1, wherein,
a plurality of the pixel circuits are arranged in a pixel circuit column in the second direction, and at least partially adjacent two second line segments of different first connection lines are separated by p pixel circuit columns, where p is an integer, and p≥1.

17. The display panel according to claim 1, wherein,
the display panel comprises a first metal layer and a second metal layer located on the side of the substrate, the first line segments are located in the first metal layer, and the second line segments are located in the second metal layer; and
the display region comprises first dummy lines extending in the first direction, and the first dummy lines are located in the first metal layer; and/or the display region comprises second dummy lines extending in the second direction, and the second dummy lines are located in the second metal layer.

18. The display panel according to claim 17, wherein,
the second dummy lines comprises first dummy line segments; and in a direction perpendicular to a plane where the substrate is located, at least one of the first dummy line segments overlaps at least two first line segments.

19. The display panel according to claim 17, wherein,
the second dummy lines comprises second dummy line segments, each of which is located between adjacent second line segments.

20. A display apparatus comprising a display panel, wherein the display panel comprises:
a substrate;
a plurality of first connection lines comprising first line segments extending in a first direction and second line segments extending in a second direction, wherein the first direction intersects the second direction, and wherein at least one of the first connection lines comprises at least two first line segments arranged at intervals;
a plurality of data lines, the data lines extending in the second direction;
a plurality of bonding pads;
a plurality of pixel circuits located on a side of the substrate, wherein the plurality of pixel circuits are arranged in pixel circuit rows in the first direction, and wherein the first line segments of two adjacent first connection lines overlap different pixel circuit rows, respectively;
a display region, wherein the first connection lines and the data lines are both located in the display region; and
a non-display region, wherein the bonding pads are located in the non-display region, and one end of each of the first connection lines is coupled to one of the data lines and the other end of the each of the first connection lines is coupled to one of the bonding pads.
